(19) United States
(12) Patent Application Publication
(10) Pub. No.: US 2021/0146781 A1
(43) Pub. Date: May 20, 2021

(54) INTEGRATED ELECTRIC POWER TRAIN

(71) Applicant: AVID TECHNOLOGY LIMITED, Cramington Northumberland (GB)

(72) Inventor: Ryan Maughan, Northumberland (GB)

(21) Appl. No.: 16/622,766

(22) PCT Filed: Jun. 15, 2018
(86) PCT No.: PCT/GB2018/051663

§ 371 Date: Dec. 13, 2019

(30) Foreign Application Priority Data
Jun. 15, 2017 (GB) 1770955.0

(51) Int. Cl. B60L 15/00; B60K 1/02; H02K 11/33; H02K 7/00; H02K 9/19; H02K 7/08; H02K 7/116; H05K 7/20

(52) U.S. Cl. CPC B60L 15/007; B60K 1/02; H02K 11/33; H02K 7/006; H02K 9/19; H02K 7/003; B60L 2240/485; H02K 7/116; H05K 7/20909; B60L 2220/50; B60L 2240/46; B60L 2240/525; H02K 7/083

(57) ABSTRACT

An integrated electric power train comprises an electric machine, a mechanical speed converter and a transfer shaft each mounted in a common housing. The mechanical speed reducer includes a plurality of wheels and an output shaft; the electric machine includes a stator and a rotor, the stator attached to one of the walls of the housing; and the rotor and one of the plurality of wheels are each mounted on the transfer shaft for the transfer of rotational power therethrough from the rotor to the output shaft.

### FIELD OF THE INVENTION

The present invention relates to power trains comprising both electric and mechanical components and in particular to an electric vehicle power train.

### BACKGROUND OF THE INVENTION

Electric vehicle power trains typically comprise an electric motor and a reduction gearbox connected together by shafts. Electronics for controlling the electric motor are typically mounted on or near the power train.

Electric motors are becoming more widely used in vehicles. Hybrid vehicles which have an internal combustion engine and an electric power unit may only have a modest size of electric motor, the purpose of which is to assist the internal combustion engine. However, in order to provide a wholly electric vehicle, or a hybrid vehicle where the electric drive is to be capable of providing full power for the vehicle, even if only for a short period of time, larger electric motors are required. As the size of a motor increases, so do the heat losses, the heat loss being proportional to the square of the current passing through the motor.

In electric cars, the typical arrangement comprises an electric motor driving the wheels of an axle via a reduction gearbox and a differential. In four wheel drive cars each axle may have its own electric motor, reduction gearbox and differential.

Motors and gearboxes generate heat and require cooling. The cooling requirements of electric motors and reduction gear boxes are different. Typically, the motor and reduction gearbox will be provided with their own cooling systems.

It would be desirable to provide a simpler arrangement of motor and reduction gearbox. It would also be desirable to provide a simpler cooling arrangement for the electric and mechanical components of an electric vehicle power train.

### SUMMARY OF THE INVENTION

According to an aspect of the invention there is provided an integrated power train comprising an electric machine, a mechanical speed converter and a transfer shaft each mounted in a common housing, wherein: the mechanical speed reducer includes a plurality of wheels and an output shaft; the electric machine includes a stator and a rotor, the stator attached to one of the walls of the housing; and wherein the rotor and one of the plurality of wheels are each mounted on the transfer shaft for the transfer of rotational power therethrough from the rotor to the output shaft.

According to an aspect of the invention there is provided an integrated electric power train comprising electric components including an electric machine and a power electronics module, a mechanical speed reducer and a transfer shaft each mounted in a common housing, wherein: the mechanical speed reducer includes a plurality of wheels and an output shaft; the electric machine includes a stator and a rotor, the stator attached to one of the walls of the housing; and wherein the rotor and one of the plurality of wheels are each mounted on the transfer shaft for the transfer of rotational power therethrough from the rotor to the output shaft, wherein the power train comprises a cooling circuit including a cooling circuit inlet and a cooling circuit outlet, and a heat exchanger situated remotely from the housing, the heat exchanger having a hot coolant inlet and a cold coolant outlet, the cooling circuit configured such that coolant exiting the cold coolant outlet enters the cooling circuit inlet and passes the power electronics module before passing the mechanical components of the power train.

Preferably, the cooling circuit is configured such that cold coolant entering the cooling circuit inlet passes the power electronics module, followed by the electric machine before passing the mechanical components of the power train.

The housing may include the cooling circuit inlet and the cooling circuit outlet.

Advantageously, the mechanical speed reducer comprises at least one speed reduction shaft mounting at least two wheels of said plurality of wheels, the at least two wheels spaced apart axially on the at least one shaft the at least one speed reduction shaft situated between the transfer shaft and the output shaft.

The at least two wheels may be toothed wheels.

Preferably, the transfer shaft is mounted in bearings attached to respective walls of the housing.

The power train may further include a motor controller power electronics module electrically connected to the stator. Advantageously, the power electronics module is attached to the housing and preferably adjacent the stator.

Preferably, the power train includes a cooling circuit including a heat exchanger situated remotely from the housing, the heat exchanger having a hot coolant inlet and a cold coolant outlet, the cooling circuit configured such that coolant exiting the cold coolant outlet passes the electric components of the power train before passing the mechanical components of the power train. This provides the advantage that the same coolant can be used to cool both the electric components of the power train, which have a greater requirement for cooling, and the mechanical components of the power train.

The cooling circuit may include a lubricant heat exchanger arranged to cool lubricant fluid in the housing.

The lubricant heat exchanger may include a chamber having a lubricant fluid inlet and a lubricant fluid outlet and wherein the cooling circuit is arranged in relation to the chamber for the transfer of heat in the lubricant fluid to the coolant fluid.

It is preferred that the coolant circuit passes through the chamber.

Preferably, the power electronics heat exchanger includes a plate upon which the power electronics module is mounted and wherein the coolant circuit passes through a fluid pathway situated on or in the plate.

The stator may be attached to one of the walls of the housing either directly or via an attachment member.

The stator may be located radially or axially of the rotor.

The integrated power train may comprise two sets of stator windings, one axially to each side of the rotor.

The integrated electric power train may include more than one electric machine and each electric machine may be associated with a separate or common power electronics module.

According to another aspect of the invention there is provided a vehicle comprising a plurality of wheels, wherein at least two of the wheels are driven and at least two integrated power trains of the first aspect of the invention, wherein each of the driven wheels is connected to the output shaft of a respective one of the at least two integrated power trains.

The vehicle may be a four wheel drive vehicle comprising four integrated electric power trains according to the first aspect of the invention, and wherein each of the four driven wheels is connected to the output shaft of a respective one of the four integrated power trains

### BRIEF DESCRIPTION OF THE DRAWINGS

In the Drawings, which illustrate preferred embodiments of the invention and are by way of example:

FIG. 1 is a schematic representation of an integrated power train according to a first embodiment of the invention;

FIG. 2 is a schematic representation of an integrated power train according to a second embodiment of the invention;

FIG. 3 is a schematic representation of a vehicle comprising an integrated power train of the type shown in FIG. 2; and

FIG. 4 is a schematic representation of the cooling arrangement of the integrated power train.

### DETAILED DESCRIPTION OF THE PREFERRED EMBODIMENTS

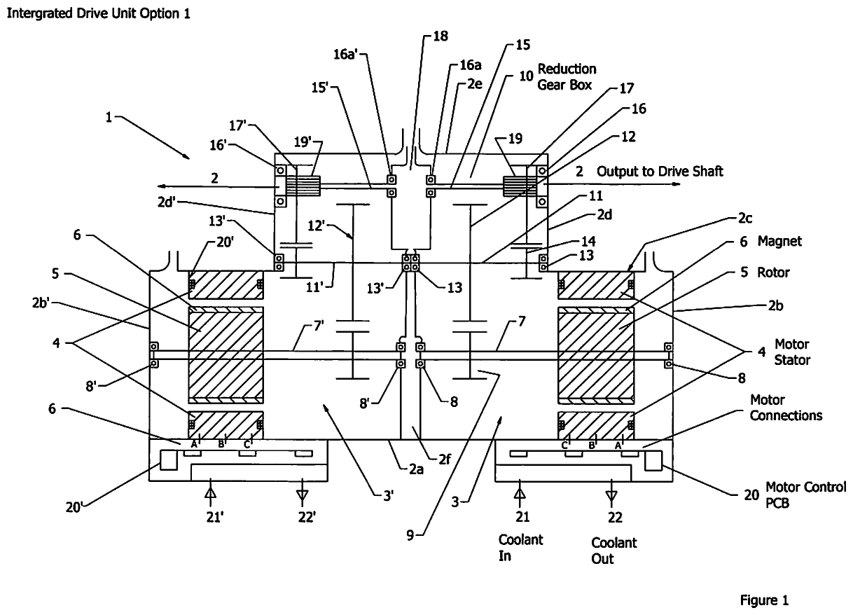

Referring now to FIG. 1, there is shown an integrated power train 1 comprising a housing 2 which houses a pair of stators and rotors and associated reduction gearboxes. The housing 1 comprises a plurality of walls 2a, 2b, 2b′, 2c, 2c′, 2d, 2d′ and 2e.

The electric machine part of the integrated power train is indicated generally by reference numerals 3, 3′ for the right and left hand electric machines respectively. The electric machines 3, 3′ each comprise a stator 4, 4′ which is attached to the walls 2a, 2d of the housing 2. Each rotor 5, 5′ is mounted on a shaft 7, 7′ which extends between and sits in bearings 8, 8′, the bearings being attached to outer walls 2b, 2b′ and the inner was 2f respectively.

Each shaft 7, 7′ mounts a gear wheel 9, 9′. The gear wheel 9, 9′ engages with a gear wheel 12, 12′ mounted on a first shaft 11, 11′ of a reduction gear set 10, 10′.

The reduction gear set 10, 10′ is mounted in the same housing 2 as the electric machines 3, 3′. The first shaft 11, 11′ extends between and is mounted in bearings 13, 13′. In the illustrated example a second gear wheel 14, 14′ is mounted on the first shaft 11, 11′ of the reduction gear set. The second gear wheel 14, 14′ engages with a gear wheel 17, 17′ which is mounted on a second shaft 15, 15′ of the reduction gear set. The second shaft 15, 15′ is mounted in bearings 16, 16a, 16′, 16a′. The bearings 16a, 16a′ are mounted on a support 18 in the housing 2. The ends of the second shaft 15, 15′ mount a spline component 19, 19′ to which a drive output shaft may be attached. Typically, each gear wheel is in the form of a cog.

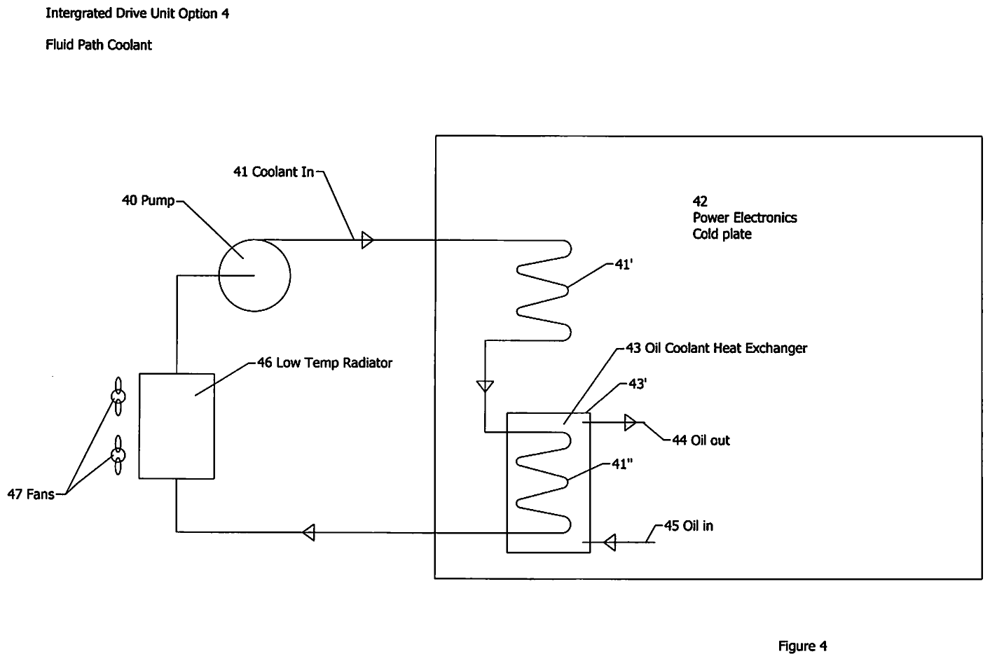

A motor control power electronics board 20, 20′ is attached to the wall 2a of the housing 2 adjacent the stator 4, 4′. The location of the power electronics board 20, 20′ provides for the convenient attachment of stator phase connections A, B, C thereto. The power electronics board 20, 20′ has a heat exchanger associated therewith, so that heat generated by the power electronics components may be transferred to a heat transfer medium in order that the power electronics components may be maintained at a temperature which is within an optimum operating temperature range. One cooling arrangement is illustrated in FIG. 4.

The housing 2 includes a heat transfer medium (coolant inlet) 21, 21′ and a heat transfer medium (coolant) outlet 22, 22′ and a heat transfer medium (coolant) pathway. The heat transfer medium (coolant) pathway is arranged such that ingoing heat transfer medium (coolant) first encounters the motor control power electronics heat exchanger. Having passed over elements of the heat exchanger the temperature of the heat transfer medium is raised. Upon exiting the aforementioned motor control power electronics heat exchanger the heat transfer medium enters the region of the housing in which the electric machine 2, 2′ is mounted and then circulates through the region of the housing in which the majority of the components of the reduction gear set are mounted. The fluid pathway includes a return that is connected to the heat transfer medium (coolant) outlet 22, 22′. The return is configured such that all the components requiring cooling in the integrated drive are cooled by the heat transfer medium before the heat transfer medium returns to the heat transfer medium (coolant) outlet.

The heat transfer medium (coolant) inlet and heat transfer medium (coolant) outlet are connected to the outlet and inlet respectively of a heat transfer medium heat exchanger, the function of which is to reduce the temperature of the heat transfer medium.

Advantageously, the heat transfer medium is the lubricant for the reduction gear set components and/or the electric machine components (to the extent that lubrication thereof is required) of the integrated power train.

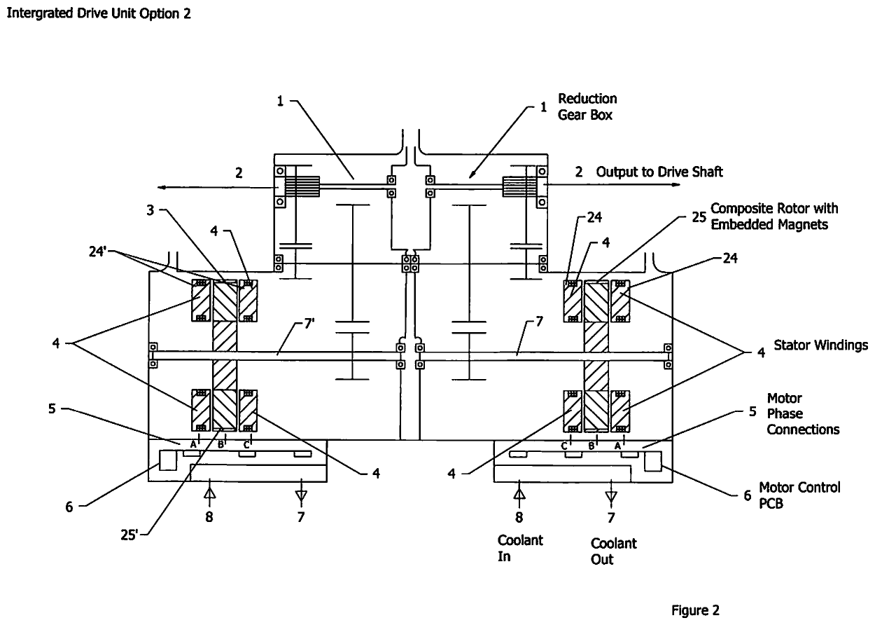

FIG. 2 illustrates an alternative arrangement of integrated power train of the invention. The principal difference between the arrangements of FIGS. 1 and 2 lies in the configuration of the stator and the rotor. The housing 2, speed reduction gear set 3, transfer shaft 7, motor control power electronics and the cooling circuit are the same in both arrangements and as such will not be described in detail. Like numerals are used to represent like parts.

The rotor 25, which is mounted on shaft 7 for rotation therewith, is a composite rotor with magnets embedded therein. Two sets of stator windings 24 are provided, one to each side of the rotor facing the flat surfaces of said rotor 25. Phase connections A, B, C connect the stator windings 24 to the motor control power electronics board 20.

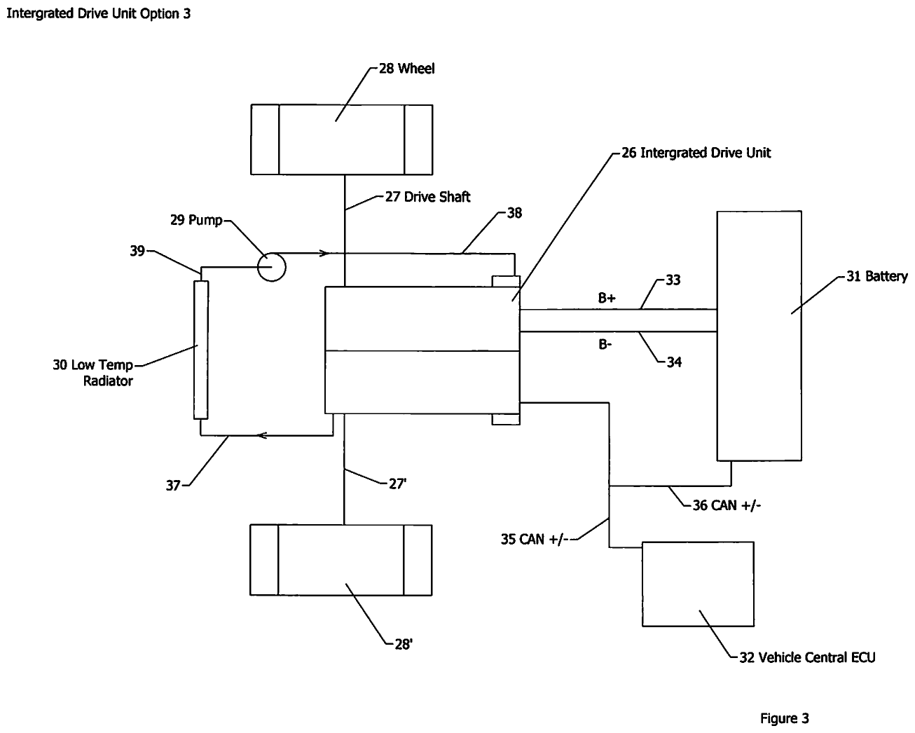

FIG. 3 illustrates a vehicle comprising integrated power train 1, which includes two electric machines 3, 3′ driving respective output shafts 27, 27′. The driven shafts 27, 27′ each have a shell 28, 28′ attached thereto. The vehicle further includes a low temperature radiator 30, a battery 31, a vehicle central controller 32.

The vehicle controller 32 communicates with the electric machines 3, 3′, including via the power electronics board 20, 20′ over a CAN bus 35, 36. The positive and negative power connections 33, 34 extend from the battery 31 to the electric machines 3, 3′.

The low temperature radiator has a coolant distribution circuit connected thereto comprising a pump 29 which pumps cold coolant fluid from the outlet of the low temperature radiator 30 along lines 39, 38 to the integrated drive 1. The coolant fluid cools the components of the integrated drive 1 and exits the said drive 1 via line 37, which returns hot coolant fluid to the low temperature radiator inlet for cooling in the low temperature radiator 30.

FIG. 4 illustrates the cooling arrangement of the in more detail. The motor control power electronics board 20 includes a cold plate 42. A coolant line 41 is connected to the outlet of a pump 40, coolant flowing out through the coolant line 41 and returns to the low temperature radiator 46. The coolant line 41 extends across the cold plate 42. Two tortuous paths 41′ and 41″ are formed in the coolant line 41. The function of the first tortuous path 41′ is to cool the power electronics board 20 and this is done by cooling the cold plate 42. The tortuous path 41′ of coolant line 41 may be formed in or on the cold plate 42. The second tortuous path 41″, which is situated down stream of the first tortuous path 41′ is located within a lubricant heat exchanger 43. The lubricant heat exchanger 43 comprises a chamber 43′ having a lubricant oil inlet 45 and an oil outlet 44. Lubricant oil flowing through the chamber 43′ is cooled by the coolant fluid passing through the tortuous path 41″ of the coolant line 41. Coolant leaving the lubricant heat exchanger 43 returns to the low temperature radiator 46 where it is cooled by the fans 47 before being pumped back into the coolant line 41.

The structure of the coolant line 41 and its relationship with the power electronics and the lubricant oil may take many forms. What is important is that the power electronics and the lubricant oil are cooled sequentially, the power electronics being cooled before the gearbox oil, and that they are cooled by the same coolant. For example, in the FIG. 2 embodiment the coolant fluid is the lubricant fluid, meaning that a separate lubricant heat exchanger is not required.

The integrated power train of the invention provides a number of advantages over the hybrid drives of the prior art. Problems with shaft alignment between electric machines and reduction gear sets when mounting such components in a vehicle for example are eliminated because the rotor of the electric machine and the first gear wheel of the reduction gear set are mounted on a common shaft. An integrated drive may be provided for each driven wheel of a vehicle. This provides a number of advantages. First, a number of smaller electric machines are more efficient than single large electric machine providing the same total amount of power output. This is because heat loss is related to the square of the current passing through a conductor. Second, in a vehicle that would typically include a differential, power is directed to the wheel encountering least resistance. Hence, if one wheel encounters a very slippery surface such as ice, most if not all the power will be transferred to that wheel. Traction control systems are used to overcome the aforementioned problem. However, these systems typically either reduce overall engine power through an engine management system or apply a brake to the wheel that is slipping. What is actually required is the maintenance of power to the wheels that are not slipping. By providing each driven wheel with its own drive, this can be achieved. The speed and torque delivered to the output shaft of the power train of the invention may be controlled via the motor control power electronics. A further advantage of the integrated drive of the invention is that it may be provided with an efficient cooling system where the same coolant is used to cool both the electronic/electrical components and the mechanical reduction gear set components, even though the cooling requirements of the electronic/electrical components have a different cooling requirement to the mechanical components. Still further, the coolant may also be the lubricant fluid for the electrical and mechanical components of the integrated power train.

1. An integrated electric power train comprising electric components including an electric machine and a power electronics module, a mechanical speed reducer and a transfer shaft each mounted in a common housing, wherein: the mechanical speed reducer includes a plurality of wheels and an output shaft; the electric machine includes a stator and a rotor, the stator attached to one of the walls of the housing; and wherein the rotor and one of the plurality of wheels are each mounted on the transfer shaft for the transfer of rotational power therethrough from the rotor to the output shaft, wherein the transfer shaft is supported on walls of the housing in bearings attached to said walls and wherein the power train comprises a cooling circuit including a cooling circuit inlet and a cooling circuit outlet, and a heat exchanger situated remotely from the housing, the heat exchanger having a hot coolant inlet and a cold coolant outlet, the cooling circuit configured such that coolant exiting the cold coolant outlet enters the cooling circuit inlet and passes the power electronics module before passing the mechanical components of the power train.

2. An integrated electric power train according to claim 1, wherein the cooling circuit is configured such that cold coolant entering the cooling circuit inlet passes the power electronics module, followed by the electric machine before passing the mechanical components of the power train.

3. An integrated electric power train according to claim 1, wherein the mechanical speed reducer comprises at least one speed reduction shaft mounting at least two wheels of said plurality of wheels, the at least two wheels spaced apart axially on the at least one shaft the at least one speed reduction shaft situated between the transfer shaft and the output shaft.

4. An integrated electric power train according to claim 3, wherein at least two wheels have different diameters.

5. An integrated electric power train according to claim 1, wherein the output shaft is mounted in bearings attached to the housing.

6. An integrated electric power train according to claim 1, wherein the power electronics module is configured for controlling the electric machine and is electrically connected to the stator.

7. An integrated electric power train according to claim 6, wherein the power electronics module is attached to the housing.

8. An integrated electric power train according to claim 7, wherein the power electronics module is attached to the housing adjacent the stator.

9. An integrated electric power train according to claim 1, wherein the power electronics module has a power electronics heat exchanger associated therewith, one side of the power electronics heat exchanger being situated directly adjacent the power electronics module for the transfer of heat therefrom to said power electronics heat exchanger.

10. An integrated electric power train according to claim 9, wherein the heat exchanger is mounted in the housing.

11. An integrated electric power train according to claim 1, wherein the housing includes the cooling circuit inlet and the cooling circuit outlet.

12. An integrated electric power train according to claim 1, wherein the cooling circuit includes a lubricant heat exchanger arranged to cool lubricant fluid in the housing.

13. An integrated electric power train according to claim 12, wherein the lubricant heat exchanger includes a chamber having a lubricant fluid inlet and a lubricant fluid outlet and wherein the cooling circuit is arranged in relation to the chamber for the transfer of heat in the lubricant fluid to the coolant fluid.

14. An integrated electric power train according to claim 13, wherein the coolant circuit passes through the chamber.

15. An integrated electric power train according to claim 9, wherein the power electronics heat exchanger includes a plate upon which the power electronics module is mounted and wherein the coolant circuit passes through a fluid pathway, the fluid pathway situated in a selected one of: on the plate and in the plate.

16. An integrated electric power train according to claim 1, wherein the stator is attached to one of the walls of the housing one of: directly and or via an attachment member.

17. An integrated electric power train according to claim 1, wherein the stator is located one of: radially and axially of the rotor.

18. An integrated electric power train according to claim 17, comprising two sets of stator windings, one axially to each side of the rotor.

19. A vehicle comprising a plurality of wheels, wherein at least two of the wheels are driven and at least two integrated electric power trains each comprising electric components including an electric machine and a power electronics module, a mechanical speed reducer and a transfer shaft each mounted in a common housing, wherein: the mechanical speed reducer includes a plurality of wheels and an output shaft the electric machine includes a stator and a rotor, the stator attached to one of the walls of the housing; and wherein the rotor and one of the plurality of wheels are each mounted on the transfer shaft for the transfer of rotational power therethrough from the rotor to the output shaft, wherein the transfer shaft is supported on walls of the housing in bearings attached to said walls, and wherein the power train comprises a cooling circuit including a cooling circuit inlet and a cooling circuit outlet, and a heat exchanger situated remotely from the housing, the heat exchanger having a hot coolant inlet and a cold coolant outlet, the cooling circuit configured such that coolant exiting the cold coolant outlet enters the cooling circuit inlet and passes the power electronics module before passing the mechanical components of the power train wherein each of the driven wheels is connected to the output shaft of a respective one of the at least two integrated power trains.

20. A vehicle comprising a plurality of wheels, wherein the vehicle is a four wheel drive vehicle and wherein the vehicle comprises four integrated electric power trains each comprising electric components including an electric machine and a power electronics module, a mechanical speed reducer and a transfer shaft each mounted in a common housing, wherein: the mechanical speed reducer includes a plurality of wheels and an output shaft: the electric machine includes a stator and a rotor, the stator attached to one of the walls of the housing; and wherein the rotor and one of the plurality of wheels are each mounted on the transfer shaft for the transfer of rotational power therethrough from the rotor to the output shaft, wherein the transfer shaft is supported on walls of the housing in bearings attached to said walls, and wherein the power train comprises a cooling circuit including a cooling circuit inlet and a cooling circuit outlet, and a heat exchanger situated remotely from the housing, the heat exchanger having a hot coolant inlet and a cold coolant outlet, the cooling circuit configured such that coolant exiting the cold coolant outlet enters the cooling circuit inlet and passes the power electronics module before passing the mechanical components of the power train, and wherein each of the four driven wheels is connected to the output shaft of a respective one of the four integrated power trains.
